(19) United States
(12) Patent Application Publication
(10) Pub. No.: US 2015/0000736 A1
(43) Pub. Date: Jan. 1, 2015

(54) SOLAR CELL

(71) Applicant: SANYO Electric Co., Ltd., Osaka (JP)

(72) Inventors: Shigeharu TAIRA, Hyogo (JP); Satoshi TOHODA, Osaka (JP)

(21) Appl. No.: 14/485,170

(22) Filed: Sep. 12, 2014

Related U.S. Application Data
(63) Continuation of application No. PCT/JP2012/057575, filed on Mar. 23, 2012.

(51) Int. Cl. H01L 31/0224

(52) U.S. Cl. CPC H01L 31/022433
USPC 136/256

(57) ABSTRACT

A solar cell has a photoelectric conversion section, and a light receiving surface electrode, which is configured by including finger electrodes and bus bar electrodes, is disposed on the light receiving surface of the photoelectric conversion section. Auxiliary electrodes are provided at the leading ends of the finger electrodes. At each of the leading ends of the finger electrodes, each of the auxiliary electrodes extends at a predetermined angle toward another adjacent finger electrode from the direction in which each finger electrode is disposed, and each of the auxiliary electrodes is disposed at a predetermined interval from the another finger electrode. The predetermined interval is specified by considering the balance between improvement of power collection efficiency and increase of shadow loss due to extension of the auxiliary electrodes.

### CROSS-REFERENCE TO RELATED APPLICATIONS

The present application is a continuation under 35 U.S.C. §120 of PCT/JP2012/057575, filed Mar. 23, 2012, which is incorporated herein by reference.

### TECHNICAL FIELD

The present invention relates to a solar cell.

### BACKGROUND ART

A solar cell performs power collection of carriers that are generated in a photoelectric conversion section as a result of light incidence. For example, Patent Literature 1 describes that power collecting electrodes formed on the light receiving surface of a photoelectric conversion section function as multiple thin wire electrodes that have a thin-wire shape and collect carriers of electrons and positive holes generated in the photoelectric conversion section, and a bus bar electrode that performs the power collection of the carriers collected by the thin wire electrodes. Here, it is described that power collecting electrodes formed on the back surface of the photoelectric conversion section also function as multiple thin wire electrodes that have a thin-wire shape and a bus bar electrode.

### CITATION LIST

### Patent Literature

Patent Literature 1: Japanese Patent Laid-Open Publication No. 2009-206493

### SUMMARY OF INVENTION

### Technical Problem

The electrodes to collect the carriers of the electrons and positive holes generated in the photoelectric conversion section are referred to as power collecting electrodes, or power collectors. Some regions require carriers generated at the outer circumference side of the photoelectric conversion section to run long distances to the leading ends of the power collectors. Therefore, it is impossible to sufficiently enhance FF={(V_{MAX}·I_{MAX} at the maximum output point)/(the open-circuit voltage V_{OC}·the short-circuit current I_{SC} at the time of photoirradiation)}, which is a performance characteristic of the solar cell.

### Solution to Problem

A solar cell according to the present invention includes a photoelectric conversion section, and multiple power collectors that are disposed on a principal surface of the photoelectric conversion section so as to be spaced from each other, in which the multiple power collectors include a first finger electrode, and a second finger electrode that is adjacent to the first finger electrode, and the solar cell further includes an auxiliary electrode that extends from a leading end of the first finger electrode toward the second finger electrode, and that is disposed at a spaced interval from the second finger electrode.

### Advantageous Effects of Invention

A solar cell according to the present invention makes it possible to sufficiently enhance FF.

### BRIEF DESCRIPTION OF DRAWINGS

FIG. 1 is a plan view of a solar cell according to an embodiment of the present invention.

FIG. 2 is a diagram showing a manner of the power collection at the leading ends of finger electrodes in a corner portion of a photoelectric conversion section, in the conventional art.

FIG. 3 is a diagram showing a manner of the power collection at the leading ends of finger electrodes in a corner portion of a photoelectric conversion section, in the solar cell according to the embodiment of the present invention.

FIG. 4 is a diagram for explaining the shadow loss and the power collection efficiency when connecting the leading ends of adjacent finger electrodes in a corner portion of a photoelectric conversion section, as a comparative example.

FIG. 5 is a diagram showing a manner of the power collection at the leading ends of finger electrodes in a parallel portion other than the corner portion of the photoelectric conversion section, in the conventional art.

FIG. 6 is a diagram showing a manner of the power collection at the leading ends of finger electrodes in a parallel portion other than the corner portion of the photoelectric conversion section, in the solar cell according to the embodiment of the present invention.

FIG. 7 is a diagram for explaining the shadow loss and the power collection efficiency when connecting the leading ends of adjacent finger electrodes in a spot other than the corner portion of the photoelectric conversion section, as a comparative example.

FIG. 8 is a diagram showing a manner of the power collection at the leading end of a finger electrode, in the conventional art.

FIG. 9 is a diagram showing a manner of the power collection at the leading end of a finger electrode having an auxiliary electrode, in the solar cell according to the embodiment of the present invention.

FIG. 10 is a plan view when a transparent conductive layer is disposed, in the solar cell according to the embodiment of the present invention.

### DESCRIPTION OF EMBODIMENTS

Embodiments of the present invention will be explained in detail below, using the drawings. Hereinafter, in all the drawings, the same reference numerals are assigned to the same elements, and repeated explanations are omitted. Further, for explanations in the text, previously described reference numerals are used as necessary.

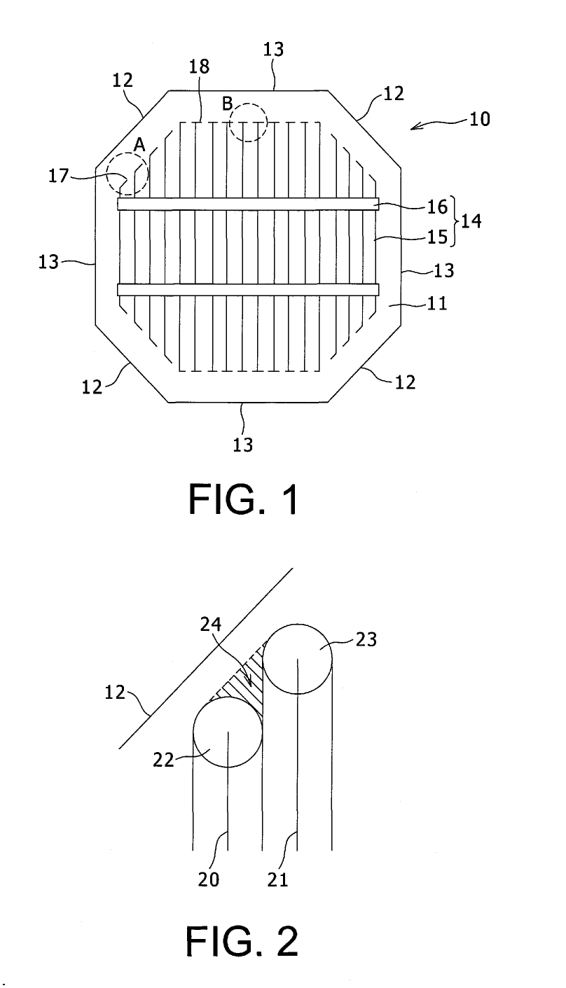

FIG. 1 is a plan view showing the configuration of a solar cell 10. The solar cell 10 has, as the principal surfaces, a light receiving surface, which is a surface that light enters from the exterior of the solar cell 10, and a back surface, which is a surface on the opposite side to the light receiving surface. FIG. 1 shows the light receiving surface.

The solar cell 10 includes a photoelectric conversion section 11 that receives light such as solar light and thereby generates a pair of photogenerated carriers of a pair of a positive hole and an electron. The photoelectric conversion section 11 has a substrate of semiconductor materials such as crystalline silicon (c-Si), gallium arsenide (GaAs) and indium phosphide (InP), for example.

The photoelectric conversion section 11 includes a p-n junction that has a function to convert light such as solar light into electricity. As the p-n junction, there can be used a p-n junction in which a p-type junction and an n-type junction are formed in the substrate of semiconductor materials using a diffusion technique. The p-n junction only needs to have a photoelectric conversion function, and may be a broad-sense p-n junction including an i-layer. For example, there can be used a heterojunction of an n-type monocrystalline silicon substrate and an amorphous silicon. The configuration of a solar cell using a heterojunction will be described later. In addition to this, for example, there may be a structure including a p-type polycrystalline silicon substrate, an n-type diffusion layer formed on the light receiving surface side, and an aluminum metal layer formed on the back surface side.

The planar shape of the photoelectric conversion section 11 is a polygonal shape in which the four corners of a square are diagonally cut out. FIG. 1 shows the diagonally cut-out portions as corner portions 12, and shows the portions between the corner portions 12 as parallel portions 13. The planar shape of the photoelectric conversion section 11 may be a shape other than this. For example, it may be a square, a rectangle, a circle, an ellipse, or the like.

The light receiving surface of the solar cell 10 is provided with a light receiving surface electrode 14 as a power collector that performs the power collection of photogenerated carriers. The light receiving surface electrode 14 is constituted by multiple finger electrodes 15 disposed parallel to each other, and bus bar electrodes 16 disposed so as to intersect with the finger electrodes 15. The finger electrodes 15 and the bus bar electrodes 16 are disposed orthogonally to each other, and are electrically connected. The finger electrodes 15, which perform the power collection from the whole of the light receiving surface, are thin wire electrodes that are formed in a thin-wire shape for reducing the light blocking. The bus bar electrodes 16 are electrodes that collect, as a whole, the carriers power-collected by the multiple finger electrodes 15, and further are connection electrodes with which wiring members are connected for extracting the collected carriers to the exterior. In that sense, the finger electrodes 15 are narrow-sense power collectors.

FIG. 1 shows eighteen finger electrodes 15 and two bus bar electrodes 16 on the light receiving surface of the solar cell 10, but these numbers are shown as an example for explanation. The numbers of the finger electrodes 15 and bus bar electrodes 16 may be other than these. Here, the back surface of the solar cell 10 is also provided with a back surface electrode having a similar configuration to the light receiving surface electrode 14. Similarly to the light receiving surface electrode 14, the back surface electrode has finger electrodes and bus bar electrodes.

For example, the finger electrode 15 and the bus bar electrode 16 are formed in an intended pattern on a transparent conductive layer, by a screen printing method with a conductive paste in which conductive fillers such as silver (Ag) are dispersed in a binder resin. Preferably, the width of the finger electrode 15 should be approximately 50 μm to 150 μm, and the thickness should be approximately 20 μm to 80 μm. Preferably, the interval between adjacent finger electrodes 15 should be approximately 1.5 mm to 3 mm. Preferably, the width of the bus bar electrode 16 should be approximately 0.1 mm to 3 mm, and the thickness should be approximately 20 μm to 100 μm.

The disposition of the finger electrodes 15 on the light receiving surface is set such that the distances from the contour line of the external shape of the photoelectric conversion section 11 are roughly equal. That is, the disposing direction of the finger electrodes 15 is parallel to the parallel portion 13 of the external shape of the photoelectric conversion section 11, and the finger electrode 15 disposed at the outermost side is disposed parallel to the parallel portion 13 of the photoelectric conversion section 11 so as to be spaced at a predetermined interval. Further, in the corner portion 12 of the photoelectric conversion section 11, the positions of the leading ends of the finger electrodes 15 are aligned so as to be spaced at the above predetermined interval from the contour line of the corner portion 12 of the photoelectric conversion section 11, and in the parallel portion 13, the positions of the leading ends of the finger electrodes 15 are aligned so as to be spaced at the above predetermined interval from the contour line of the parallel portion 13 of the photoelectric conversion section 11. Thereby, it is possible to effectively collect carriers from the whole of the light receiving surface of the photoelectric conversion section 11, to the finger electrodes 15.

At the leading ends of the finger electrodes 15, auxiliary electrodes 17, 18 are provided. The auxiliary electrodes 17, 18 have a function to more efficiently perform the power collection of carriers generated at the outer circumference side of the photoelectric conversion section 11.

The auxiliary electrodes 17 are provided at the leading ends of the finger electrodes 15 in the corner portion 12 of the photoelectric conversion section 11. In the corner portion 12 of the photoelectric conversion section 11, the positions of the leading ends of the multiple finger electrodes 15 are aligned parallel to the external shape of the photoelectric conversion section 11, and the disposing-directional lengths of the multiple finger electrodes 15 are different. An auxiliary electrode 17 provided at one finger electrode 15 extends in the direction parallel to the external shape of the photoelectric conversion section 11, toward the leading end of a different adjacent finger electrode 15 that has a longer disposing-directional length than the finger electrode 15, and does not extend toward the leading end of a different adjacent finger electrode 15 that has a shorter disposing-directional length than the finger electrode 15. That is, the auxiliary electrode 17 extends from the leading end of the finger electrode 15, only to one side.

The auxiliary electrodes 18 are provided at the leading ends of the finger electrodes 15 in the parallel portion 13 of the photoelectric conversion section 11. The parallel portion 13 can be disposed in the direction parallel to the disposing direction of the finger electrode 15 or in the direction perpendicular to the disposing direction of the finger electrode 15. In the latter case, the auxiliary electrodes 18 are provided at the leading ends of the finger electrodes 15 in the parallel portion 13. In this parallel portion 13, the positions of the leading ends of the multiple finger electrodes 15 are aligned parallel to the external shape of the photoelectric conversion section 11, and the disposing-directional lengths of the multiple finger electrodes 15 are equal. An auxiliary electrode 18 provided at one finger electrode 15 extends in the direction parallel to the external shape of the photoelectric conversion section 11, toward different adjacent finger electrodes 15 at both sides of the finger electrode 15, respectively. That is, the auxiliary electrode 18 extends from the leading end of the finger electrode 15, to both sides.

Thus, the ways in which the auxiliary electrodes 17, 18 are disposed differ between the corner portion 12 and parallel portion 13 of the photoelectric conversion section 11. However, in both cases, they extend from the leading ends of the finger electrodes 15 toward the different adjacent finger electrodes, at predetermined angles with respect to the disposing direction of the finger electrodes 15, and are disposed at predetermined spaced intervals from the different finger electrodes 15. That is, the auxiliary electrodes 17, 18 do not connect the leading ends of the adjacent finger electrodes 15 with each other.

Here, the predetermined spaced intervals are specified from the balance between the improvement of power collection efficiency and the increase in shadow loss, which are due to the extension of the auxiliary electrodes 17, 18. The manner in which the intervals are determined will be explained using FIG. 2 to FIG. 7.

FIG. 2 to FIG. 4 are schematic diagrams for explaining the manner of the power collection at the leading ends of finger electrodes in a corner portion 12 that is shown as the A portion in FIG. 1. The description is here given for two finger electrodes 20, 21 in the corner portion 12. The finger electrodes 20, 21 are disposed parallel to each other at a previously specified disposing interval, and therefore, the power collection ranges for which the finger electrodes 20, 21 have charge are respectively regions from the finger electrodes 20, 21 to one-half of this disposing interval. At the leading ends of the finger electrodes 20, 21, the power collection ranges are circles 22, 23 whose diameters are this disposing interval.

FIG. 2 shows a case of the conventional art in which the auxiliary electrodes are not used. In this case, there is a region 24 away from the circle 22 that is the power collection range for the leading end of the finger electrode 20 and the circle 23 that is the power collection range for the leading end of the finger electrode 21. The carriers generated in this region 24 run longer distances to the leading ends of the finger electrodes 20, 21, compared to the carriers generated in the ranges of the circles 22, 23. Therefore, it is impossible to sufficiently perform the power collection of the carriers generated in this region 24.

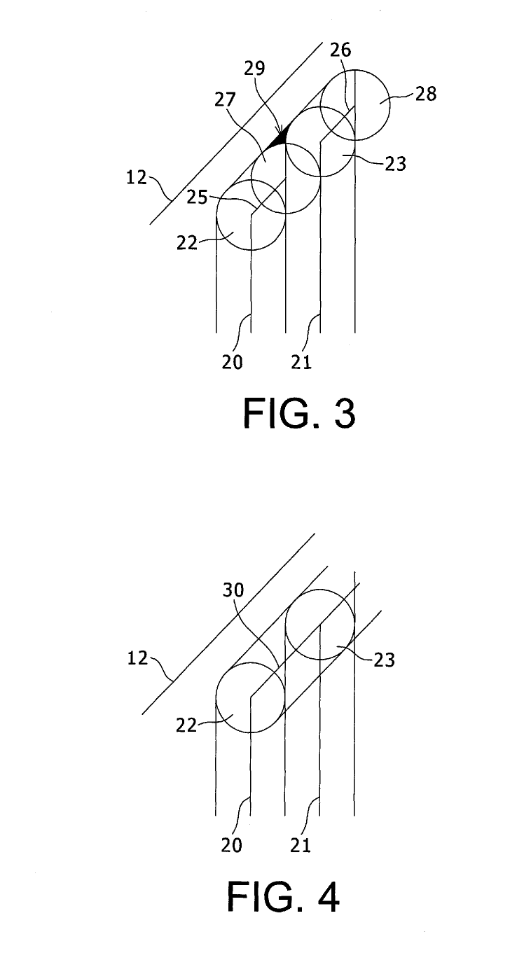

FIG. 3 is a diagram that schematically shows the configuration shown in FIG. 1. The finger electrode 20 is provided with an auxiliary electrode 25, and the finger electrode 21 is provided with an auxiliary electrode 26. The auxiliary electrodes 25, 26 extend respectively from the leading ends of the finger electrodes 20, 21, parallel to the contour line of the external shape of the corner portion 12. The extending direction is the direction toward a finger electrode having a longer disposing-directional length. In the example of FIG. 3, the disposing-directional length of the finger electrode 21 is longer than the disposing-directional length of the finger electrode 20, and therefore, the auxiliary electrode 25 extends from the leading end of the finger electrode 20 toward the leading end of the finger electrode 21. The auxiliary electrode 26 extends from the leading end of the finger electrode 21 toward the leading end of a further rightward finger electrode not shown in the figure.

The auxiliary electrode 25 extends, but does not connect with the leading end of the finger electrode 21. In the example of FIG. 3, it extends by one-half of the distance between the leading end of the finger electrode 20 and the leading end of the finger electrode 21, so as to be spaced from the leading end of the finger electrode 21. This is to take into consideration the fact that the connection by the auxiliary electrode between the leading end of the finger electrode 20 and the leading end of the finger electrode 21 results in light blocking at the intermediate region in the photoelectric conversion section 11, and an increase in shadow loss.

When the finger electrode 20 is a first finger electrode, the finger electrode 21 is a second finger electrode that is adjacent to the first finger electrode, and the auxiliary electrode 25 extends from the leading end of the first finger electrode toward the leading end of the second finger electrode. Further, the spaced distance provided between the auxiliary electrode 25 and the leading end of the second finger electrode is equal to the length of the auxiliary electrode 25.

The power collection range for the leading end of the auxiliary electrode 25 is shown by a circle 27, and the power collection range for the leading end of the auxiliary electrode 26 is shown by a circle 28. Therefore, the power collection range for the finger electrode 20 and the auxiliary electrode 25 is a range into which the circle 22 and the circle 27 are combined. Similarly, the power collection range for the finger electrode 21 and the auxiliary electrode 26 is a range into which the circle 23 and the circle 28 are combined. A region 29 away from these power collection ranges is drastically reduced in largeness, compared to the region 24 in FIG. 1. Thus, by providing the auxiliary electrodes 25, 26, it is possible to collect almost all the carriers that, in the configuration in FIG. 2, run long distances to the leading ends of the finger electrodes 20, 21.

FIG. 4 is a diagram showing a configuration in which the leading end of the finger electrode 20 and the leading end of the finger electrode 21 are connected by an auxiliary electrode 30. This configuration allows the remaining region 29 in FIG. 3 to disappear. However, because the auxiliary electrode 30 is provided, this configuration results in light blocking at a region bridging between the leading end of the finger electrode 20 and the leading end of the finger electrode 21, and an increase in shadow loss in the photoelectric conversion section 11.

Thus, the configuration in FIG. 2 reduces the shadow loss but exhibits a low power collection efficiency, and the configuration in FIG. 4 improves the power collection efficiency but increases the shadow loss. Hence, preferably, the auxiliary electrode should extend such that a predetermined spaced interval is provided and thereby the adjacent finger electrodes are not connected. That is, the auxiliary electrode is extended such that a predetermined spaced interval is provided that is specified from the balance between the improvement of power collection efficiency and the increase in shadow loss, which are due to the extension of the auxiliary electrode.

As will be understood from FIG. 3, when the auxiliary electrode is extended by approximately one-half of the disposing interval between the adjacent finger electrodes, the power collection efficiency is drastically improved. The shadow loss is one-half of the case of FIG. 4. From this, as an example, the predetermined spaced distance can be approximately one-half of the disposing interval between the adjacent finger electrodes. Needless to say, this is shown as an example, and an appropriate setting can be performed depending on the specification of the solar cell 10.

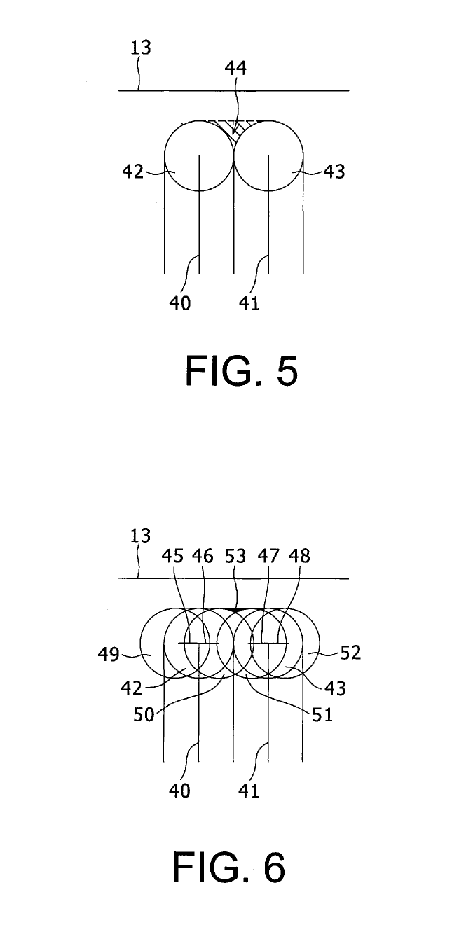

FIG. 5 to FIG. 7 are schematic diagrams for explaining the manner of the power collection at the leading ends of finger electrodes in a parallel portion 13 that is shown as the B portion in FIG. 1. The description is given made for two finger electrodes 40, 41 in the parallel portion 13. The finger electrodes 40, 41 are disposed parallel to each other at a previously specified disposing interval, and therefore the power collection ranges of which the finger electrodes 40, 41 have charge are respectively regions from the finger electrodes 40, 41 to one-half of this disposing interval. At the leading ends of the finger electrodes 40, 41, the power collection ranges are circles 42, 43 whose diameters are this disposing interval.

FIG. 5 shows a case of the conventional art in which the auxiliary electrodes are not used. In this case, there is a region 44 away from the circle 42 that is the power collection range for the leading end of the finger electrode 40 and the circle 43 that is the power collection range for the leading end of the finger electrode 41. The carriers generated in this region 44 run longer distances to the leading ends of the finger electrodes 40, 41, compared to the carriers generated in the ranges of the circles 42, 43. Therefore, it is impossible to sufficiently perform the power collection of the carriers generated in this region 44.

FIG. 6 is a diagram that schematically shows the configuration shown in FIG. 1. The finger electrode 40 is provided with auxiliary electrodes 45, 46, and the finger electrode 41 is provided with auxiliary electrodes 47, 48. The auxiliary electrodes 45, 46 extend from the leading end of the finger electrode 40, parallel to the contour line of the external shape of the parallel portion 13. Similarly, the auxiliary electrodes 47, 48 extend from the leading end of the finger electrode 41, parallel to the contour line of the external shape of the parallel portion 13. The extending directions of the auxiliary electrodes 45, 46 are the directions toward different adjacent finger electrodes at both sides of the finger electrode 40, and the extending directions of the auxiliary electrodes 47, 48 are the directions toward the leading ends of different adjacent finger electrodes at both sides of the finger electrode 41. In the example in FIG. 6, the auxiliary electrode 45 extends from the leading end of the finger electrode 40 in the direction toward a further leftward finger electrode not shown in the figure, and the auxiliary electrode 46 extends from the leading end of the finger electrode 40 toward the leading end of the finger electrode 41. Similarly, the auxiliary electrode 47 extends from the leading end of the finger electrode 41 toward the leading end of the finger electrode 40, and the auxiliary electrode 48 extends from the leading end of the finger electrode 41 toward the leading end of a further rightward finger electrode not shown in the figure.

These auxiliary electrodes 45, 46, 47, 48 extend, but do not connect with the leading ends of the adjacent finger electrodes. In the example of FIG. 6, the auxiliary electrodes 45, 46, 47, 48 extend by one-quarter of the distance between the leading end of the finger electrode 40 and the leading end of the finger electrode 41, so as to be spaced from the leading ends of the adjacent finger electrodes. This is in order to take into consideration the fact that the connection by the auxiliary electrode between the leading end of the finger electrode 40 and the leading end of the finger electrode 41 results in light blocking at the intermediate region in the photoelectric conversion section 11, and an increase in shadow loss.

When the finger electrode 40 is a first finger electrode, the finger electrode 41 is a second finger electrode that is adjacent to the first finger electrode, and a finger electrode not shown in the figure that is at the opposite side to the second finger electrode and is adjacent to the first finger electrode is a third finger electrode. Here, the leading end of the first finger electrode is disposed so as to be aligned parallel to the parallel portion 13, together with the leading end of the second finger electrode and the leading end of the third finger electrode. The length of the first finger electrode is equal to the lengths of the second finger electrode and third finger electrode. The auxiliary electrode 46 extends toward the leading end of the second finger electrode, and the auxiliary electrode 45 extends toward the leading end of the third finger electrode. Further, the total length of the auxiliary electrodes provided at the leading end of the first finger electrode, which is a length resulting from summing the auxiliary electrode 45 and the auxiliary electrode 46, is equal to the total length of the auxiliary electrodes provided at the leading end of the second finger electrode, which is a length resulting from summing the auxiliary electrode 47 and the auxiliary electrode 48. Further, the spaced distance between the auxiliary electrodes at the leading end of the first finger electrode and the auxiliary electrodes at the leading end of the second finger electrode, which is the spaced distance between the auxiliary electrode 46 and the auxiliary electrode 47, is equal to the total length of the auxiliary electrodes provided at the leading end of the first finger electrode and the total length of the auxiliary electrodes provided at the leading end of the second finger electrode.

The power collection ranges for the leading ends of the auxiliary electrodes 45, 46, 47, 48 are shown by circles 49, 50, 51, 52, respectively. Therefore, the power collection range for the finger electrode 40 and the auxiliary electrodes 45, 46 is a range into which the circle 49 and the circle 50 are combined. Similarly, the power collection range for the finger electrode 41 and the auxiliary electrodes 47, 48 is a range into which the circle 51 and the circle 52 are combined. A region 53 away from these power collection ranges is drastically reduced in largeness, compared to the region 44 in FIG. 5. Thus, by providing the auxiliary electrodes 45, 46, 47, 48, it is possible to collect almost all the carriers that, in the configuration in FIG. 5, run long distances to the leading ends of the finger electrodes 40, 41.

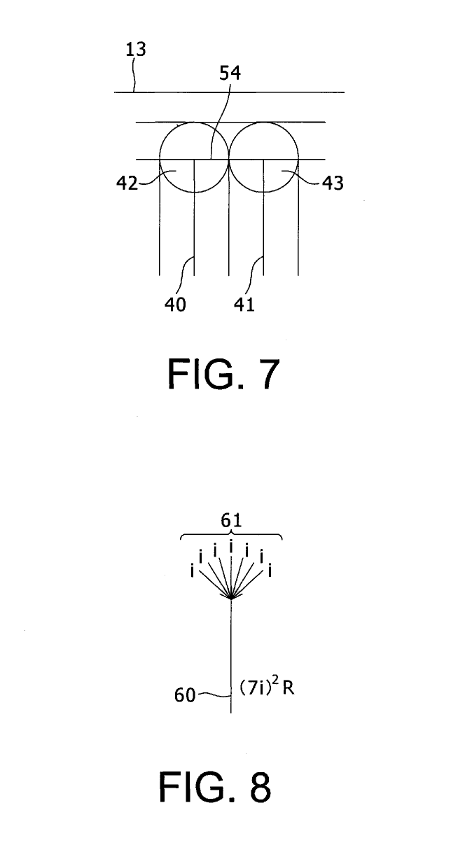

FIG. 7 is a diagram showing a configuration in which the leading end of the finger electrode 40 and the leading end of the finger electrode 41 are connected by an auxiliary electrode 54. This configuration allows the remaining region 53 in FIG. 6 to disappear. However, because the auxiliary electrode 54 is provided, this configuration results in light blocking at a region bridging between the leading end of the finger electrode 40 and the leading end of the finger electrode 41, and an increase in shadow loss in the photoelectric conversion section 11.

Thus, similarly to the case of the corner portion 12, in the parallel portion 13, the configuration in FIG. 5 reduces the shadow loss but exhibits a low power collection efficiency, and the configuration in FIG. 7 improves the power collection efficiency but increases the shadow loss. Hence, preferably, the auxiliary electrode should extend such that a predetermined spaced interval is provided and thereby the adjacent finger electrodes are not connected. That is, the auxiliary electrode is extended such that a predetermined spaced interval is provided that is specified from the balance between the improvement of power collection efficiency and the increase in shadow loss, which are due to the extension of the auxiliary electrode.

As will be understood from FIG. 6, when the auxiliary electrodes are extended to both sides of the finger electrode by approximately one-quarter of the disposing interval between the adjacent finger electrodes, the power collection efficiency is drastically improved. From this, as an example, the predetermined spaced distance can be approximately one-half of the disposing interval between the adjacent finger electrodes. Needless to say, this is shown as an example, and an appropriate setting can be performed depending on the specification of the solar cell 10.

In FIG. 3 and FIG. 6, it has been explained that the extending direction of the auxiliary electrode is parallel to the contour line of the external shape of the photoelectric conversion section 11. In consideration of the balance between the improvement of power collection efficiency and the increase in shadow loss, the extending direction of the auxiliary electrode may be appropriately inclined relative to the contour line of the external shape of the photoelectric conversion section 11.

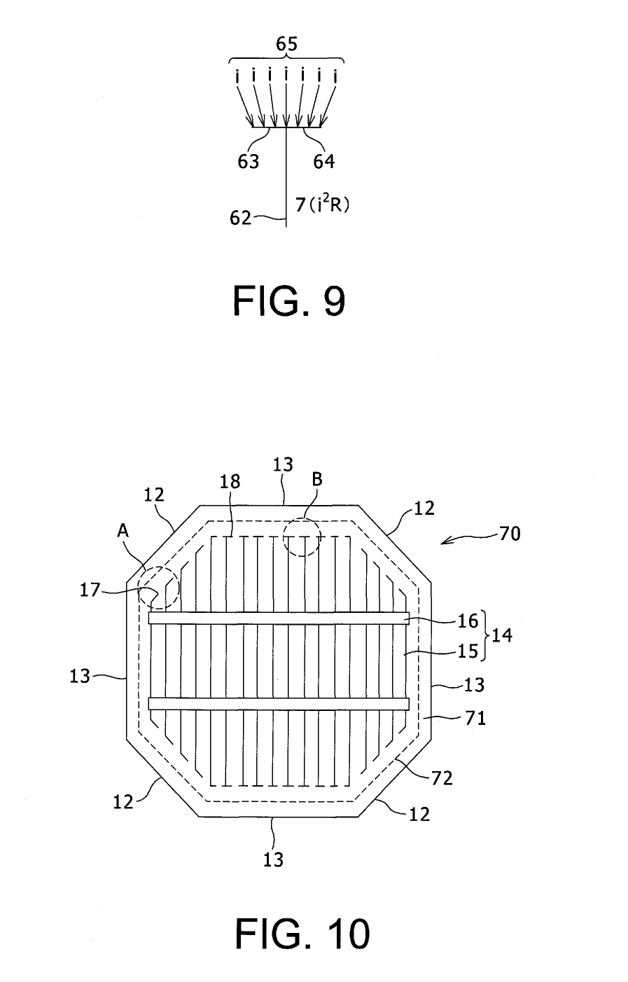

By providing the auxiliary electrode, improvement of power collection efficiency can be achieved. In addition, the effect of inhibiting the resistance loss is exerted. FIG. 8 and FIG. 9 are diagrams for explaining the manner in which the resistance loss is reduced.

FIG. 8 is a diagram showing the resistance loss for the current to flow in a finger electrode 60 that is not provided with the auxiliary electrode. Here, R is the resistance value of the finger electrode 60. When currents that are collected from various directions to the leading end of the finger electrode 60 each have a magnitude of i, FIG. 8 shows a case of performing of the power collection of a current of i, from seven directions, respectively. Currents 61 from these seven directions converge at one point of the leading end of the finger electrode 60, and therefore, a current of (7i) flows in the finger electrode 60. Accordingly, the resistance loss in the finger electrode 60 is calculated as (7i)²R.

FIG. 9 is a diagram showing a case in which auxiliary electrodes 63, 64 are provided at both sides of the leading end of a finger electrode 62, respectively. This structure corresponds to the B portion in FIG. 1, and FIG. 6. Similarly to FIG. 8, R is the resistance value of the finger electrode 62, and it is assumed that the power collection of a current of i is performed from seven directions, respectively. Here, the power collection of currents 65 from the seven directions is performed dispersedly on the auxiliary electrodes 63, 64, and therefore, the seven currents of i flow separately in the finger electrode 62. Accordingly, the resistance loss in the finger electrode 62 is calculated as 7(i²R).

Comparing FIG. 8 and FIG. 9, by providing the auxiliary electrodes, the resistance loss of the finger electrode is inhibited to one-seventh. Although this is an example in which the power collection is performed from seven directions, by providing the auxiliary electrode, the current convergence at the leading end of the finger electrode is dispersed, and the resistance loss of the finger electrode is inhibited.

A solar cell 70 shown in FIG. 10 is a diagram showing a configuration that includes a photoelectric conversion section 71 using a heterojunction. A heterojunction of an n-type monocrystalline silicon substrate and an amorphous silicon is used here, and in this case, an i-type amorphous silicon layer and a p-type amorphous silicon layer in which boron (B) or the like has been doped are formed on the light receiving surface side of a substrate, resulting in an n-i-p junction. Then, thereon, there is laminated a transparent conductive oxide layer (TCO) that is composed of a transparent conductive oxide of indium oxide (In₂O₃), for example. The light receiving surface electrode 14 is formed on this transparent conductive oxide layer 72. Here, the back surface side of the substrate can adopt a laminated structure of an i-type amorphous silicon layer, an n-type amorphous silicon layer in which phosphorus (P) or the like has been doped, and a transparent conductive oxide layer.

Here, the power collection of the carriers generated in the photoelectric conversion section 71 is performed on the light receiving surface electrode 14 through the transparent conductive oxide layer 72. Hence, in this case, preferably, the contour line of the external shape of the transparent conductive oxide layer 72 should be used, although the position of the leading end of the finger electrode has been explained with reference to the contour line of the external shape of the photoelectric conversion section in FIG. 1, FIG. 3 and FIG. 6. That is, assuming that the contour line of the external shape of the corner portion of the transparent conductive oxide layer 72 is the contour line of the external shape of the corner portion 12 in FIG. 3, and the contour line of the external shape of the parallel portion of the transparent conductive oxide layer 72 is the contour line of the external shape of the parallel portion 13 in FIG. 6, the auxiliary electrode can be extended along the external shape of the transparent conductive oxide layer 72.

Thus, by providing the auxiliary electrode, it is possible to improve the FF of the solar cell, and, since the power collection of the currents from the periphery is performed dispersedly, it is possible to inhibit the resistance loss. Further, a predetermined spaced interval is provided between the adjacent finger electrodes, and the shadow loss is inhibited. Therefore, it is possible to achieve an output enhancement for the whole of the solar cell.

### INDUSTRIAL APPLICABILITY

A solar cell according to the present invention can be utilized for a solar cell module in which multiple solar cells are connected.

1. A solar cell comprising:
a photoelectric conversion section; and
multiple power collectors that are disposed on a principal surface of the photoelectric conversion section so as to be spaced from each other,
wherein the multiple power collectors include a first finger electrode, and a second finger electrode that is adjacent to the first finger electrode, and
the solar cell further comprises an auxiliary electrode that extends from a leading end of the first finger electrode toward the second finger electrode, and that is disposed at a spaced interval from the second finger electrode.

2. The solar cell according to claim 1,
wherein the auxiliary electrode extends toward a leading end of the second finger electrode.

3. The solar cell according to claim 2,
wherein the leading end of the first finger electrode is disposed so as to be aligned with the leading end of the second finger electrode, parallel to an external shape of the photoelectric conversion section, and
the first finger electrode is longer in length than the second finger electrode.

4. The solar cell according to claim 2,
wherein the multiple power collectors further include a third finger electrode that is adjacent to the first finger electrode at an opposite side to the second finger electrode,
the leading end of the first finger electrode is disposed so as to be aligned with the leading end of the second finger electrode and a leading end of the third finger electrode, parallel to the external shape of the photoelectric conversion section,
the first finger electrode is equal in length to the second finger electrode and the third finger electrode, and
the auxiliary electrode extends toward the leading end of the third finger electrode.

5. The solar cell according to claim 2,
further comprising a transparent conductive oxide layer that is disposed between the photoelectric conversion section and the multiple power collectors,
wherein the leading end of the first finger electrode is disposed so as to be aligned with the leading end of the second finger electrode, parallel to the external shape of the transparent conductive oxide layer, and
the first finger electrode is longer in length than the second finger electrode.

6. The solar cell according to claim 2,
further comprising a transparent conductive oxide layer that is disposed between the photoelectric conversion section and the multiple power collectors,
wherein the multiple power collectors further include a third finger electrode that is adjacent to the first finger electrode at an opposite side to the second finger electrode,
the leading end of the first finger electrode is disposed so as to be aligned with the leading end of the second finger electrode and a leading end of the third finger electrode, parallel to the external shape of the transparent conductive layer,
the first finger electrode is equal in length to the second finger electrode and the third finger electrode.

7. The solar cell according to claim 3,
wherein the auxiliary electrode of the first finger electrode and the leading end of the second finger electrode are disposed such that a spaced distance therebetween is equal to a length of the auxiliary electrode.

8. The solar cell according to claim 5,
wherein the auxiliary electrode of the first finger electrode and the leading end of the second finger electrode are disposed such that a spaced distance therebetween is equal to a total length of the auxiliary electrode.

9. The solar cell according to claim 4,
wherein the auxiliary electrode of the first finger electrode and the auxiliary electrode of the second finger electrode are disposed such that a spaced distance therebetween is equal to a total length of the auxiliary electrode, the total length of the auxiliary electrode being a length resulting from summing a length of an auxiliary electrode extending from the first finger electrode toward the leading end of the second finger electrode and a length of an auxiliary electrode extending from the first finger electrode toward the leading end of the third finger electrode.

10. The solar cell according to claim 6,
wherein the auxiliary electrode of the first finger electrode and the auxiliary electrode of the second finger electrode are disposed such that a spaced distance therebetween is equal to a total length of the auxiliary electrode, the total length of the auxiliary electrode being a length resulting from summing a length of an auxiliary electrode extending from the first finger electrode toward the leading end of the second finger electrode and a length of an auxiliary electrode extending from the first finger electrode toward the leading end of the third finger electrode.
